(19) United States
(12) Patent Application Publication
(10) Pub. No.: US 2007/0259191 A1
(43) Pub. Date: Nov. 8, 2007

(54) SPUTTER TARGET OF A SILVER ALLOY, ITS USE AND GLASS SUBSTRATE WITH THERMAL INSULATION LAYER

(75) Inventors: Christoph SIMONS, Biebergemund (DE); Martin WEIGERT, Hanau (DE)

Correspondence Address: AKIN GUMP STRAUSS HAUER & FELD L.L.P., ONE COMMERCE SQUARE, 2005 MARKET STREET, SUITE 2200, PHILADELPHIA, PA, 19103, US

(73) Assignee: W.C. HERAEUS GMBH, Hanau (DE)

(21) Appl. No.: 11/758,153

(22) Filed: Jun. 5, 2007

Related U.S. Application Data
(63) Continuation of application No. PCT/EP05/13083, filed on Dec. 7, 2005.

(30) Foreign Application Priority Data
Dec. 10, 2004 (DE) 10 2004 059 876.2

(51) Int. Cl. B32B 15/00; C23C 14/00

(52) U.S. Cl. 428/432; 428/434; 204/192.15; 204/298.13

(57) ABSTRACT

A sputter target is provided having a sputter material made of a silver alloy comprising silver and at least one further element selected from the group of Mg, Ca, Co, Sc, Y, La, Ce, Pr, Nd, Sm, Eu, Gd, Th, Dy, Ho, Er, Tm, Yb, and Lu. The at least one further element is present in the alloy in a proportion of >50 at. ppm, respectively, and a total proportion of the group of <5 at. %. The sputter targets may be used to produce a glass substrate having a thermal insulation layer.

### CROSS-REFERENCE TO RELATED APPLICATIONS

This application is a continuation of International Application No. PCT/EP2005/013083, filed Dec. 7, 2005, which was published in the German language on Jun. 15, 2006, under International Publication No. WO 2006/061195 A2, the disclosure of which is incorporated herein by reference.

### BACKGROUND OF THE INVENTION

The invention relates to a sputter target of a silver alloy, the use of the sputter target and the alloy, and a glass substrate with a thermal insulation layer.

Thermal insulation layers for architectural glass or motor vehicle glass consist, as a rule, of sputtered multiple layers. Such layer packages frequently exhibit a dielectric layer sputtered onto the glass. On top of this, a layer of silver is sputtered. On top of the silver layer, a blocking layer is arranged and, on top of this, a dielectric anti-reflex layer is arranged. Layer structures with two silver layers separated by a dielectric layer are also known. Heat-treatable layer systems, in particular, are of industrial interest, e.g., for the manufacture of thermally insulating safety glass or for the manufacture of flexible motor vehicle glass panes. Following the thermal treatment of such layer packages, degradation of the silver layer frequently takes place, for example, by oxidation of the metallic silver layer or by diffusion of the silver, which may lead to macroscopically visible discoloration stains.

Such a layer structure is known from German published patent application DE 35 03 851 A1. In this case, the silver layer is provided with dopings of high-melting metals, such as tungsten, rhenium, tantalum, osmium, niobium, molybdenum, or iridium, in order to improve the homogeneity and conductivity of the silver layer. The doping elements used have a high melting point and, partially, a poor miscibility with silver. The corresponding sputter targets are made by powder metallurgical processes.

Similar coatings are known from European Patent EP 1 060 140 B1. In this case, layer structures with silver alloys are disclosed, in which a second metal component is present with a proportion of 5 to 20 at. % (atomic percent), which is present in the oxidized state in the boundary regions of the metal layer to the adjacent oxide layers. The elements introduced by alloying act as oxygen getters in order to avoid the oxidation of the silver.

Silver targets are known from European patent application publication EP 1 331 280 A1. In this case, doping elements are used as oxygen getters in order to avoid the absorption of oxygen within the sputter target. In particular, cracks of piping targets formed at the grain boundaries are to be avoided thereby, in order to guarantee a vacuum tightness of the piping target. Further, silver targets with a proportion of Nd for the manufacture of reflective layers on plastic carriers in information recording media are known from German published patent application DE 101 52 889 A1, although it is known from German published patent application DE 103 36 228 A1 that silver neodymium does not exhibit any NaCl resistance as a material for reflective layers in information recording media.

### BRIEF SUMMARY OF THE INVENTION

An object of the present invention comprises providing improved sputter targets from which the manufacture of improved thermal insulation layers on glass substrates is possible.

A sputter target having a sputter material of a silver alloy which, apart from silver, contains one or several further elements from the group of Mg, Ca, Co, Sc, Y, La, Ce, Pr, Nd, Sm, Eu, Gd, Th, Dy, Ho, Er, Tm, Yb, Lu, in a proportion of >50 at. ppm, respectively, and in a total proportion from the group of <5 at. % is excellently suitable for the manufacture of thermal insulation layers on glass substrates.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawing:

FIG. 1 is a schematic side view of a glass substrate with a multi-layer structure according to an embodiment of the invention.

### DETAILED DESCRIPTION OF THE INVENTION

According to the invention, the thermal insulation layer of a glass substrate consequently exhibits, apart from silver, one or several further elements selected from the group of Mg, Ca, Co, Sc, Y, La, Ce, Pr, Nd, Sm, Eu, Gd, Th, Dy, Ho, Er, Tm, Yb, Lu in a proportion of >50 at. ppm respectively and in a total proportion of the group of <5 at. %. Such layers do not exhibit any deflagration effects, which otherwise arise during annealing of the coated glass pane. The sputter targets can be made by simple melting and conversion processes. As further elements, the elements of the group of rare earths, in this case in particular neodymium, are used advantageously as alloy components. A proportion of the further element of >500 at. ppm, preferably of >1000 at. ppm, with a total proportion of the group of <5 at. % has proved advantageous in this case.

Similarly advantageous is that the one or more further elements are present essentially as an intermetallic phase, both in the sputter target and in the thermal insulation layer of the glass substrate. In particular, a glass substrate is preferred which exhibits, at its surface, a multi-layer system having at least one thermal insulation layer. As a rule, the layer described above serves as the main thermal insulation layer, the silver essentially effecting a radiation reflection of infrared rays, each further layer being able to act in a more or less thermally insulating manner, depending on its formation.

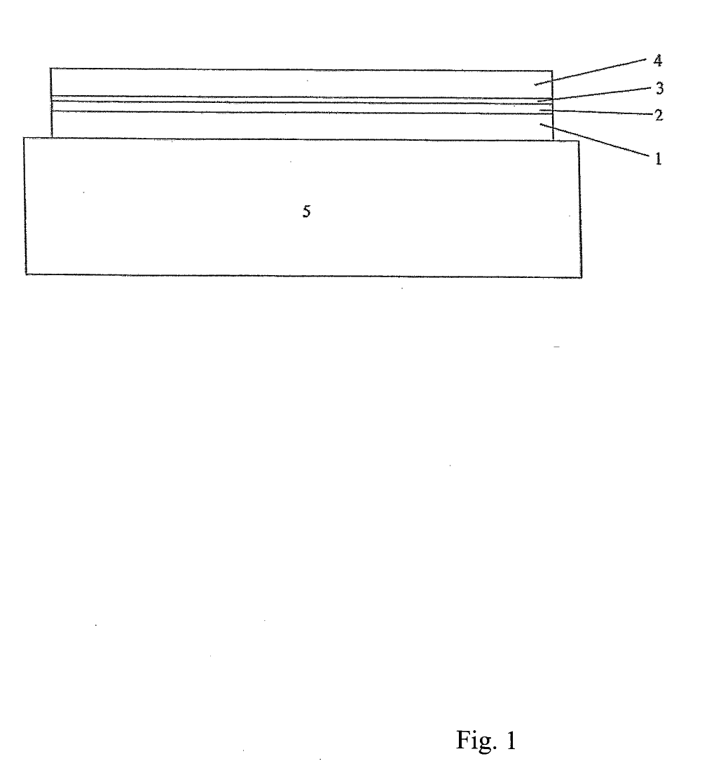

As shown in the embodiment of FIG. 1, a base dielectric layer 1 is arranged directly on the glass substrate 5. This was sputtered onto the glass substrate 5. It consists of SnO₂, ZnO, TiO₂, Bi₂O₃ or Si₃N₄ and has a thickness of approx. 30 nm. On top of that, a silver layer 2 having a layer thickness of approx. 12 nm is sputtered. On top of the silver layer 2, a blocking layer 3 of NiCr or Ti/TiO_{2-X} is sputtered in a thickness of approx. 2 nm as corrosion protection for the silver layer. Finally, a dielectric anti-reflection layer 4 is applied by sputtering in a thickness of approx 30 nm. This anti-reflection layer 4 consists of SnO₂, ZnO, TiO₂, Bi₂O₃, Si₃N₄ or of mixed oxides of Si and Al or of Zn and Sn.

An arrangement of several silver layers 2 on top of each other is possible, these being then separated by a dielectric layer approx. 30 to 60 nm thick, similar to the dielectric layer 1. The silver layer 2 consists of an alloy of silver with neodymium, neodymium being present in a proportion of less than 5 at. %.

The silver layer is made using a sputter target, which can be made as follows, for example:

### EXAMPLE 1

In a vacuum induction furnace, 500 kg of alloy consisting of 467.1 kg Ag and 32.9 kg Nd (corresponding to 5 at. % Nd) are melted and cast in a metal casting mold in the form of a block having the dimensions 120×240×1700 mm. This cast block is heated to 350° C. and converted by hot rolling at 350° C. into sheet metal with the dimensions 21×240×9700 mm. Three sputter targets having the dimensions 3050×232×18 mm can be milled from this sheet metal. The manufacture of a sputter target with 0.3 at. % Nd (from 498 kg Ag and 2 kg Nd) is effected in an analogous manner.

### EXAMPLE 2

In a vacuum induction furnace, 370 kg Ag and 10 kg Nd are melted to form an alloy corresponding to Ag 2 at. % Nd. The casting of the alloy takes place in a casting mold of the hollow cylinder type, in such a way that a cast blank is formed having the dimensions: outside diameter=197 mm, inside diameter=121 mm, length 1000 mm. This cast blank is converted by extruding at 300° C. into an elongated tube having the dimensions: inside diameter=125 mm, outside diameter=158 mm, length 260 mm. The extruded tube is changed by turning to the target dimensions of inside diameter=125 mm, outside diameter=152 mm tube length. The manufacture of a sputter target having 1.0 at. % Nd (from 394.8 kg Ag and 5.2 kg Nd) is effected in an analogous manner.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

I/we claim:

1. A sputter target comprising a sputter material of a silver alloy, the silver alloy containing in addition to silver at least one further element selected from the group consisting of Mg, Ca, Co, Sc, Y, La, Ce, Pr, Nd, Sm, Eu, Gd, Th, Dy, Ho, Er, Tm, Yb, and Lu, the at least one further element being present in the alloy in a proportion of >50 at. ppm, respectively, and a total proportion of the group being <5 at. %.

2. The sputter target according to claim 1, wherein the at least one further element exhibits a proportion of >1000 at. ppm, respectively, and a total proportion of the group being <5 at. %.

3. The sputter target according to claim 1, wherein the at least one further element is present essentially as an intermetallic phase.

4. A method for producing thermal insulation layers on glass substrates, comprising using a sputter target according to claim 1.

5. A method for producing thermal insulation layers, comprising using a sputter material comprising a silver alloy containing in addition to silver at least one further element selected from the group consisting of Mg, Ca, Co, Sc, Y, La, Ce, Pr, Nd, Sm, Eu, Gd, Tb, Dy, Ho, Er, Tm, Yb, and Lu, the at least one further element being present in a proportion of >50 at. ppm, respectively, and a total proportion of the group being <5 at. %.

6. A glass substrate having a thermal insulation layer, wherein the thermal insulation layer contains silver and at least one further element selected from the group consisting of Mg, Ca, Co, Sc, Y, La, Ce, Pr, Nd, Sm, Eu, Gd, Th, Dy, Ho, Er, Tm, Yb, and Lu, the at least one further element being present in a proportion of >50 at. ppm, respectively, and a total proportion of the group being <5 at. %.

7. The glass substrate according to claim 6, wherein the at least one further element is present in a proportion of >1000 at. ppm, respectively, and a total proportion of the group being <5 at. %.

8. The glass substrate according to claim 6, wherein the at least one further element is substantially present as an intermetallic phase.

9. The glass substrate according to claims 6, wherein, at its surface, the substrate has a multi-layer system comprising at least one thermal insulation layer.
